(19) United States
(12) Patent Application Publication
(10) Pub. No.: US 2021/0364274 A1
(43) Pub. Date: Nov. 25, 2021

(54) PROCESSING APPARATUS, MEASUREMENT METHOD, AND ARTICLE MANUFACTURING METHOD

(71) Applicant: CANON KABUSHIKI KAISHA, Tokyo (JP)

(72) Inventors: Shinichi Shudo, Saitama (JP); Masataka Yasukawa, Tochigi (JP)

(21) Appl. No.: 17/320,312

(22) Filed: May 14, 2021

(30) Foreign Application Priority Data
May 21, 2020 (JP) 2020-089073

(51) Int. Cl. G01B 11/06; G03F 7/00

(52) U.S. Cl. CPC G01B 11/0608; G03F 7/0002

(57) ABSTRACT

A processing apparatus includes a height measurement device configured to perform first measurement of measuring a height of at least one measurement point of a measurement target region and second measurement of measuring heights of a plurality of measurement points of the measurement target region, a pressure measurement device configured to measure an air pressure that influences results of the first measurement and the second measurement by the height measurement device, and a calculator configured to obtain shape information representing a shape of the measurement target region by correcting the result of the second measurement by the height measurement device based on the result of the first measurement by the height measurement device and a result of measurement of the air pressure by the pressure measurement device.

### BACKGROUND OF THE INVENTION

### Field of the Invention

The present invention relates to a processing apparatus, a measurement method, and an article manufacturing method.

### Description of the Related Art

As pattern forming apparatuses for forming a pattern on a substrate, an imprint apparatus and an exposure apparatus are known. The imprint apparatus brings an imprint material on a substrate into contact with a mold, and cures the imprint material, thereby forming a pattern of the imprint material. The exposure apparatus transfers a pattern of an original to a photoresist applied to a substrate to form a latent image, and develops the latent image, thereby forming a resist pattern.

In the imprint apparatus, it is important to control the relative posture between the surface of the substrate and the pattern surface of the mold when bringing the imprint material on the substrate into contact with the pattern surface of the mold. If the relative posture is inappropriate, fall of the pattern formed on the substrate, a failure of filling of the imprint material in a concave portion of the mold or in the space between the substrate and the mold, or the like may occur. In the exposure apparatus, to control the shot region of the substrate within the focal depth of a projection optical system, it is important to make the surface of the substrate parallel to the imaging plane of the projection optical system.

Japanese Patent Laid-Open No. 2006-156508 discloses a technique of measuring the thickness distribution of a substrate and the height distribution of a holding surface for holding the substrate in advance in an exposure apparatus using a projection optical system and obtaining the height distribution of the surface of the substrate held by the holding surface based on the measurement results. Japanese Patent Laid-Open No. 2018-22114 discloses a technique of measuring the surface of a substrate in two directions different from each other in an exposure apparatus using a projection optical system, thereby shortening the time needed to measure the height distribution of the surface of the substrate.

A movable body on which a substrate holder for holding a substrate is mounted can be driven and positioned in a state in which the movable body is floated by an air pressure on a guide surface. The air pressure can be provided from a plant facility to the pattern forming apparatus. If the air pressure varies, the height of the substrate may vary. In processing of measuring the shape of a substrate by measuring the height of the substrate at a plurality of measurement points of the measurement target region of the substrate, if the air pressure varies, the influence of the pressure variation may appear in the measurement result.

### SUMMARY OF THE INVENTION

The present invention provides a technique advantageous in reducing measurement errors caused by a variation of an air pressure.

One of aspects of the present invention provides a processing apparatus comprising: a height measurement device configured to perform first measurement of measuring a height of at least one measurement point of a measurement target region and second measurement of measuring heights of a plurality of measurement points of the measurement target region; a pressure measurement device configured to measure an air pressure that influences results of the first measurement and the second measurement by the height measurement device; and a calculator configured to obtain shape information representing a shape of the measurement target region by correcting the result of the second measurement by the height measurement device based on the result of the first measurement by the height measurement device and a result of measurement of the air pressure by the pressure measurement device.

Further features of the present invention will become apparent from the following description of exemplary embodiments with reference to the attached drawings.

### BRIEF DESCRIPTION OF THE DRAWINGS

FIG. 1 is a view showing the arrangement of an imprint apparatus (processing apparatus) according to the first embodiment;

FIG. 2 is a view showing a detailed example of the arrangement of a substrate driving mechanism;

FIGS. 3A and 3B are views for explaining first measurement by a height measurement device;

FIG. 4 is a view for explaining second measurement by the height measurement device;

FIG. 5 is a flowchart showing a measurement method according to the first embodiment;

FIGS. 6A and 6B are views for explaining first measurement according to the second embodiment;

FIGS. 7A and 7B are views for explaining second measurement according to the second embodiment;

FIG. 8 is a flowchart showing a measurement method according to the second embodiment;

FIG. 9 is a view showing the arrangement of an imprint apparatus (processing apparatus) according to the third embodiment;

FIGS. 10A and 10B are views for explaining first measurement according to the third embodiment;

FIG. 11 is a view for explaining second measurement according to the third embodiment;

FIG. 12 is a flowchart showing a measurement method according to the third embodiment;

FIGS. 13A and 13B are views for explaining first measurement according to the fourth embodiment;

FIGS. 14A and 14B are views for explaining second measurement according to the fourth embodiment; and

FIG. 15 is a flowchart showing a measurement method according to the fourth embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

The present invention can be applied to various processing apparatuses in which a measurement result of the height or shape of a measurement target region is influenced by a variation of an air pressure. Such a processing apparatus can be, for example, a pattern forming apparatus such as an imprint apparatus or an exposure apparatus. Alternatively, such a processing apparatus can be, for example, a coating apparatus, an etching apparatus, or a cleaning apparatus. An example in which the present invention is applied to an imprint apparatus will be described below. It is obvious that the present invention can be applied to another processing apparatus based on the following explanation.

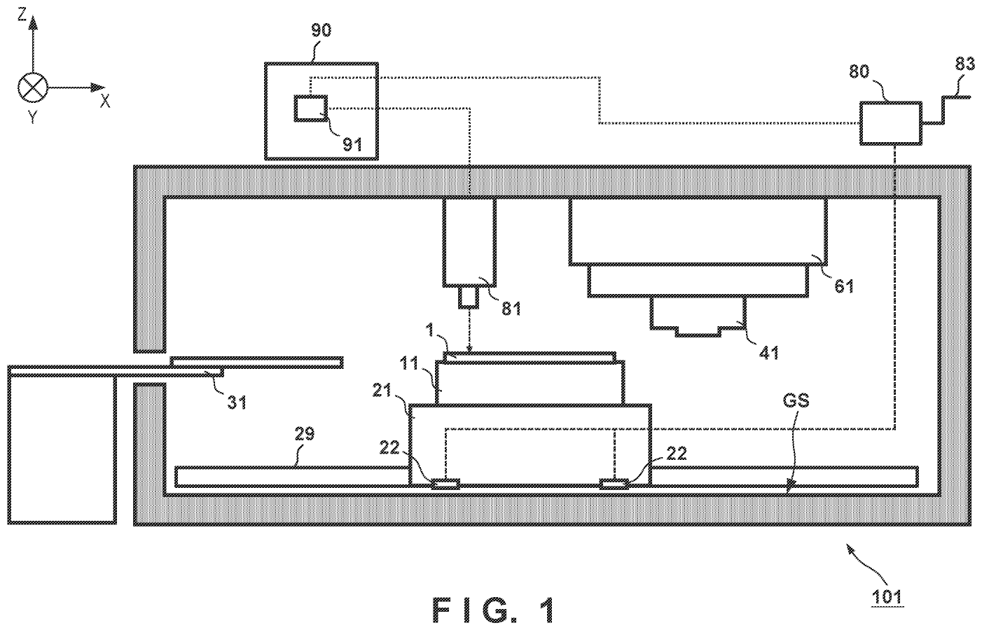

FIG. 1 shows the arrangement of an imprint apparatus 101 according to the first embodiment. The imprint apparatus 101 brings an imprint material on a shot region of a substrate 1 into contact with the pattern surface of a mold 41 and cures the imprint material, thereby forming a pattern of the imprint material on the shot region. As the imprint material, a material (curable composition) to be cured by receiving curing energy is used. An electromagnetic wave, heat, or the like is used as the curing energy. The electromagnetic wave includes, for example, light whose wavelength is selected from the range of 10 nm (inclusive) to 1 mm (inclusive), more specifically, infrared rays, visible light rays, and ultraviolet rays. The curable composition is a composition cured by light irradiation or heat application. A photo-curable composition cured by light irradiation contains at least a polymerizable compound and a photopolymerization initiator, and may further contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component. The imprint material may be applied in a film shape onto the substrate by a spin coater or a slit coater. The imprint material may be applied, onto the substrate, in a droplet shape or in an island or film shape formed by connecting a plurality of droplets by using a liquid injection head. The viscosity (the viscosity at 25° C.) of the imprint material is, for example, 1 mPa·s (inclusive) to 100 mPa·s (inclusive). As the substrate, glass, ceramic, a metal, a semiconductor, a resin, or the like is used. A member made of a material different from that of the substrate may be formed on the surface of the substrate, as needed. More specifically, examples of the substrate are a silicon wafer, a compound semiconductor wafer, and silica glass.

The imprint apparatus 101 performs imprint processing of forming the pattern of the imprint material on the substrate 1 using the mold 41. The imprint processing can include a contact step, a curing step executed after the contact step, and a separation step executed after the curing step. In the contact step, the imprint material on a portion of the shot region of the substrate 1 can be brought into contact with the pattern surface of the mold 41, and after that, the contact region between the imprint material and the pattern surface can be expanded to the whole shot region. In the curing step, the imprint material can be cured in a state in which the imprint material on the shot region of the substrate 1 and the pattern surface of the mold 41 are in contact. In the separation step, the cured product of the imprint material on the shot region of the substrate 1 and the pattern surface of the mold 41 can be separated. The imprint apparatus 101 may include a dispenser configured to arrange the imprint material on the substrate 1. In this case, the imprint processing can include an arrangement step of arranging the imprint material on the substrate 1 by the dispenser before the contact step.

The imprint apparatus 101 can include a movable body 21 floated by an air pressure above a guide surface GS, a substrate holder 11 mounted on the movable body 21, and a substrate driving mechanism 29 that drives the substrate 1 by driving the movable body 21. The substrate holder 11 can hold the substrate 1 by vacuum chucking, electrostatic chucking, mechanical chucking, or the like. The movable body 21 includes an injector 22 (an air bearing or an air guide) and can be driven in horizontal directions (X and Y directions) by the substrate driving mechanism 29 while maintaining a state in which air is injected via the injectors 22, and the movable body 21 floats above the guide surface GS. The floating amount can be, for example, several μm. The air can be, for example, clean dry air. The air can be supplied from, for example, a plant facility in which the imprint apparatus 101 is installed to the imprint apparatus 101 via a supply path 83. The imprint apparatus 101 can include, for example, a pressure measurement device 80 that measures the pressure of air supplied to the injectors 22 via the supply path 83. The pressure measurement device 80 may be arranged, for example, in the movable body 21, may be arranged near a connecting portion that connects the imprint apparatus 101 and the plant facility, or may be arranged at another position. The imprint apparatus 101 can include a mold holder 51 that holds the mold 41, and a mold driving mechanism 61 that drives the mold 41 by driving the mold holder 51.

The imprint apparatus 101 may include a substrate conveying mechanism 31 that loads the substrate 1 onto the substrate holding surface of the substrate holder 11 or unloads the substrate 1 on the substrate holding surface to the outside of the imprint apparatus 101. The substrate conveying mechanism 31 may include a rotation mechanism that rotates the substrate 1 about an axis (an axis parallel to the vertical direction) orthogonal to its surface. The rotation mechanism may be implemented by, for example, rotating the link mechanism of a plurality of robot hands, may be implemented by rotating the robots themselves, or may be implemented by another mechanism. The rotation mechanism may measure the rotation angle using an orientation marker such as a notch provided on the outer peripheral portion of the substrate 1 or may measure the rotation angle using an encoder or the like.

The imprint apparatus 101 can include a height measurement device 81 that measures the height (the position in the Z direction) of the measurement target region of the substrate 1. The height measurement device 81 can measure the heights of a plurality of measurement points in the measurement target region. The measurement target region can include at least a part of the surface of the substrate 1. In an example, the position in the horizontal direction (X and Y directions) at which the height is measured by the height measurement device 81 can be adjusted by adjusting the position of the substrate 1 in the horizontal direction by the substrate driving mechanism 29. The height measurement device 81 can be, for example, a laser displacement gauge or a spectral interferometer, but may be a measurement device of another type. The height measurement device 81 can be configured to, for example, measure the distance (for example, the optical path length difference) between a reference position and the measurement target region of the substrate 1. The height measurement device 81 can be configured or controlled to perform first measurement of measuring the height of at least one measurement point of the measurement target region of the substrate 1 and second measurement of measuring the heights of a plurality of measurement points of the measurement target region of the substrate 1.

The imprint apparatus 101 can include a calculator 91. The calculator 91 can be formed by, for example, a PLD (an abbreviation of Programmable Logic Device) such as an FPGA (an abbreviation of Field Programmable Gate Array) or an ASIC (an abbreviation of Application Specific Integrated Circuit), or a general-purpose or dedicated computer incorporating a program, or a combination of some or all of these components. The calculator 91 may form the whole or a part of a controller 90 that controls the imprint apparatus 101. The calculator 91 can perform a calculation of obtaining shape information representing the shape of the measurement target region of the substrate 1 by correcting the result of second measurement by the height measurement device 81 based on the result of first measurement by the height measurement device 81 and the result of measurement by the pressure measurement device 80.

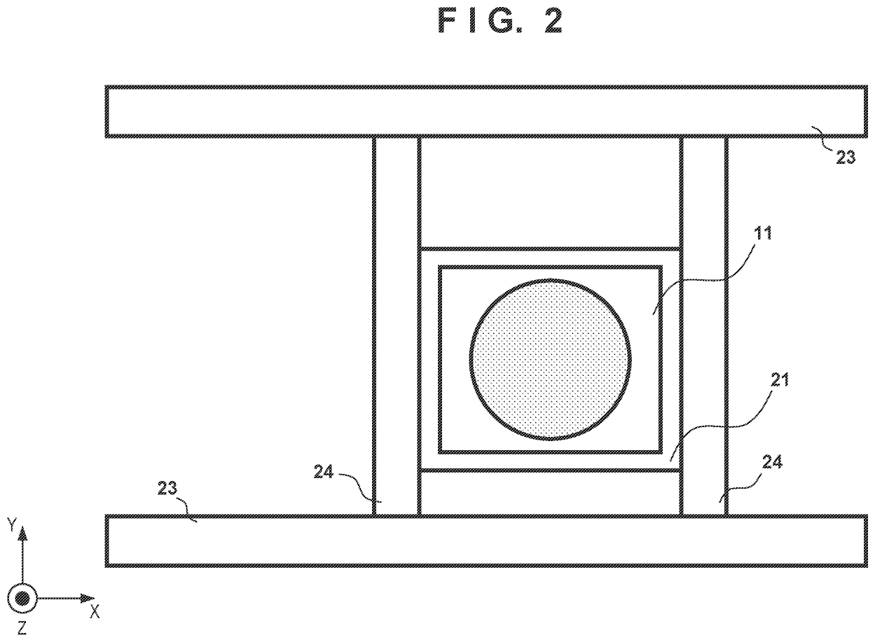

FIG. 2 shows a detailed example of the arrangement of the substrate driving mechanism 29. The substrate driving mechanism 29 can include a first driving mechanism 23 that drives the movable body 21 in the X direction while guiding it concerning the X direction, and a second driving mechanism 24 that drives the movable body 21 in the Y direction while guiding it concerning the Y direction. The position of the movable body 21 is measured by a position measurement device (not shown). The position measurement device can be formed by, for example, an encoder or a scale. The controller 90 can control the position of the movable body 21 by controlling the first driving mechanisms 23 and the second driving mechanisms 24 based on the result of position measurement by the position measurement device.

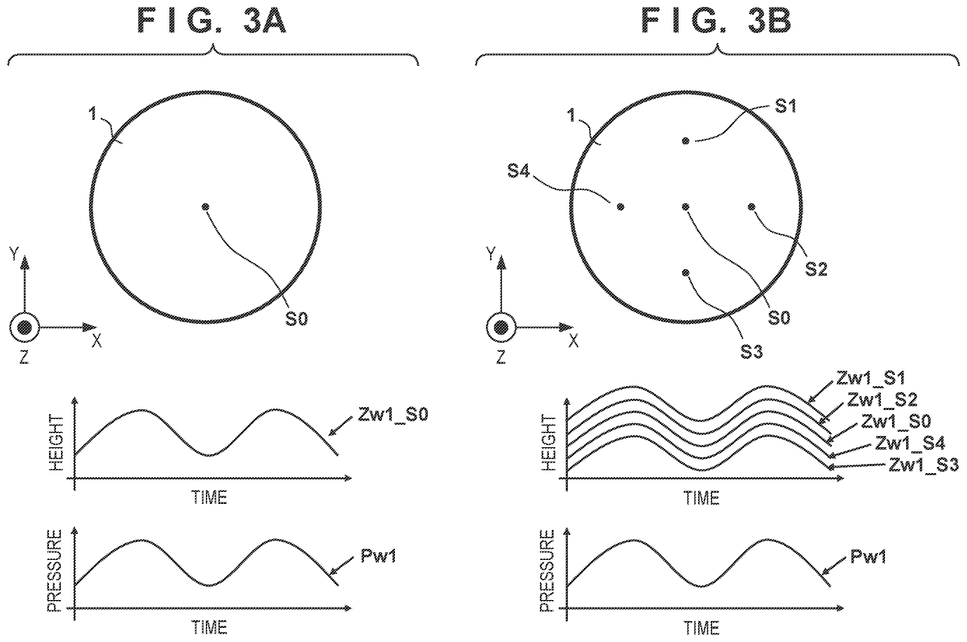

FIGS. 3A and 3B schematically show first measurement of measuring the height of at least one measurement point of the measurement target region of the substrate 1 by the height measurement device 81. Here, a result of measuring the height (the position in the Z direction) of a measurement point in the measurement target region of the substrate 1 by the height measurement device 81 is indicated by a symbol including Zw1, and the pressure of air measured by the pressure measurement device 80 in synchronism with the height measurement device 81 is indicated by Pw1. A suffix added to Zw1 represents the position of the measurement target point in the horizontal direction (X and Y directions).

A pressure variation of air provided by the plant facility depends on the performance of a pump used to supply the air and is periodical. The pressure variation width of the air provided by the plant facility changes depending on the plant facility, and the air pressure can have a variation width of, for example, several tens of kPa. In a semiconductor manufacturing apparatus, air supplied from a plant can be controlled to a desired pressure value or a pressure variation width using a pressure control valve or the like and used. If accurate pressure control is required, the pressure variation width can be suppressed to several kPa using a precision pressure control valve or the like.

In the imprint apparatus 101, the contact step can be executed in a state in which the mold 41 is tilted by the mold driving mechanism 61 such that the substrate surface and the pattern surface of the mold 41 become parallel in each shot region. Hence, the imprint apparatus 101 may be, for example, required to measure the height distribution (shape) of the measurement target region of the substrate 1 on a nanometer order. However, in the arrangement in which the floating amount of the movable body 21 is influenced by the variation of the air pressure provided from the plant facility, even if the pressure variation is suppressed to several kPa by a precision pressure control valve, the floating amount may vary within the range of several tens of nanometers. Additionally, in some cases, the structure that supports the movable body 21 or the height measurement device 81 is also floated by an air mount system to relax the influence of a vibration component from the floor. In this case, the structure may also be influenced by the pressure variation of the air provided from the plant facility. Also, even if a height measurement device 82 and the movable body 21 are supported by different structures in consideration of a vibration caused by driving of the movable body 21, one of these may be influenced by the pressure variation of the air supplied from the plant facility.

FIG. 3A shows the result of measuring a variation of the height at the measurement point using, as the measurement point, one measurement point (here, an origin S0) on an XY coordinate system with the origin at the center of the substrate 1. It can be considered that a proportional relationship holds in a very small region (for example, a submicron order) between a variation width ΔZw1 of the height measurement result by the height measurement device 81 and a variation width ΔPw1 of the pressure measurement result by the pressure measurement device 80 at the origin S0. Hence, letting K0 be the correction coefficient at the origin S0,

ΔZw1_S0=K0×ΔPw1_S0 (1)

holds.

The height of the movable body 21 that almost maintains the horizontal posture varies in accordance with equation (1). Hence, letting Kw be the correction coefficient used to correct the height measured by the height measurement device 81, the correction coefficient Kw used when the height is measured only at the origin S0 can be given by

Kw=K0 (2)

FIG. 3B shows the result of measuring a variation of the height at each of the measurement points using, as the measurement points, the origin S0 on the XY coordinate system with the origin at the center of the substrate 1, points S2 and S4 on the X-axis, and points S1 and S3 on the Y axis. As in the above-described case, it can be considered that a proportional relationship holds in a very small region between the variation width ΔZw1 of the height measurement result by the height measurement device 81 and the variation width ΔPw1 of the pressure measurement result by the pressure measurement device 80 at each measurement point. Hence, letting K1, K2, K3, and K4 be the coefficients, equations (3), (4), (5), and (6) are obtained. A suffix represents a measurement point.

ΔZw1_S1=K1×ΔPw1_S1 (3)

ΔZw1_S2=K2×ΔPw1_S2 (4)

ΔZw1_S3=K3×ΔPw1_S3 (5)

ΔZw1_S4=K4×ΔPw1_S4 (6)

Since the height of the movable body 21 changes following the variation of the air pressure in accordance with equations (1), (3), (4), (5), and (6), the correction coefficient Kw used when the heights of the five measurement points S0 to S4 are measured can be given by

Kw=(K4−K2)÷(K4_x−K2_x)×X+(K3−K1)÷(K3_y−K1_y)×Y+K0 (7)

where K2_x and K4_x represent the x-coordinates of the measurement points S2 and S4, and K1_y and K3_y represent the y-coordinates of the measurement points S1 and S3. In addition, X and Y represent an arbitrary point on the substrate 1 on the XY coordinate system.

In this example, the measurement points are set to the origin S0, the points S2 and S4 on the X-axis, and the points S1 and S3 on the Y-axis. However, the number and positions of measurement points are not limited to this example, and arbitrary points on the substrate 1 can be set to measurement points. In addition, the first measurement by the height measurement device 81 and the air pressure measurement by the pressure measurement device 80 are preferably performed at least for one period of the variation of the air pressure.

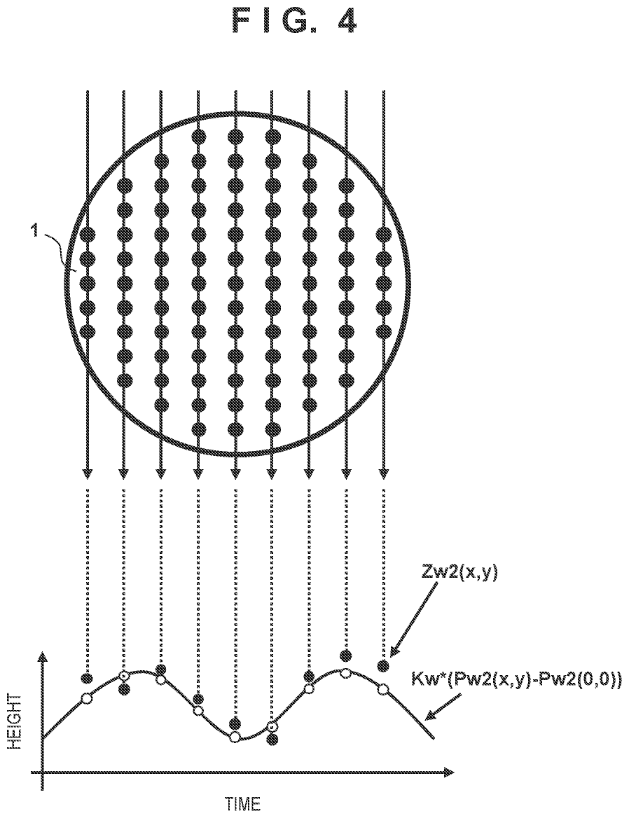

FIG. 4 schematically shows second measurement of measuring the heights of a plurality of measurement points of the measurement target region of the substrate 1 by the height measurement device 81. The plurality of measurement points of the measurement target region in the second measurement can be determined such that the measurement points are arranged on each of a plurality of lines parallel to the Y direction. Let Zw2(x, y) be the result of measurement in the second measurement by the height measurement device 81, and Pw2(x, y) be the result of measurement by the pressure measurement device 80 in synchronism with the height measurement device 81. Since Zw2(x, y) varies following the variation of the air pressure measured by the pressure measurement device 80, a distribution Zwt1(x, y) of heights in the measurement target region of the substrate 1 after the variation of the air pressure is removed is given by

Zwt1(x,y)=Zw2(x,y)−Kw×(Pw2(x,y)−Pw2(0,0)) (8)

where Pw2(0, 0) is a pressure measured by the pressure measurement device 80 when measuring the height of the origin (0, 0) of the XY coordinate system on the substrate 1. However, an arbitrary point on the substrate 1 can be set to the reference point. In addition, the arrangement of the plurality of measurement points in the second measurement by the height measurement device 81 (or the scanning method of the substrate 1) may be determined such that the measurement points are arranged on each of a plurality of lines parallel to the X direction. Alternatively, the arrangement of the plurality of measurement points in the second measurement by the height measurement device 81 (or the scanning method of the substrate 1) may be determined such that the measurement points are arranged on each of a plurality of lines in an oblique direction with respect to the X or Y direction. Alternatively, the arrangement of the plurality of measurement points in the second measurement by the height measurement device 81 (or the scanning method of the substrate 1) may be determined such that the plurality of measurement points are arranged on a spiral line.

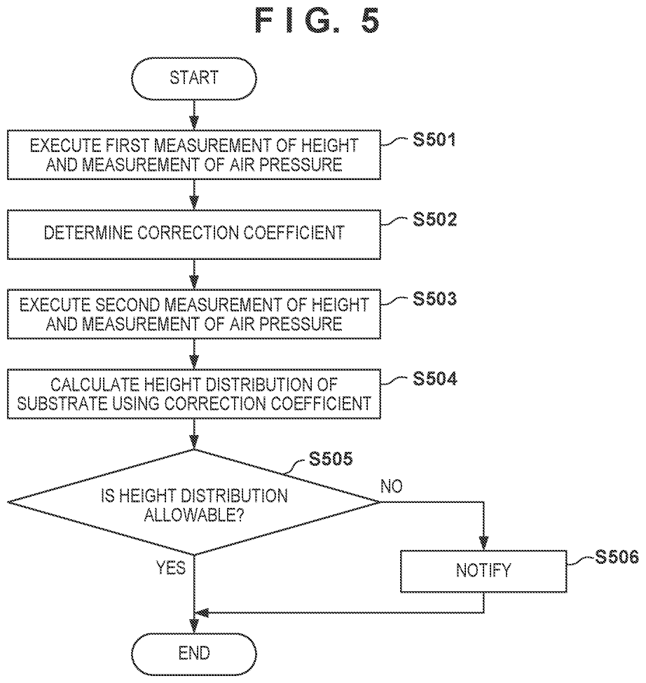

FIG. 5 shows a measurement method according to the first embodiment. The measurement method shown in FIG. 5 can be controlled by the controller 90. The measurement method shown in FIG. 5 can be incorporated in a procedure of controlling imprint processing. For example, the measurement method shown in FIG. 5 is executed when the substrate 1 is loaded onto the substrate holder 11 of the imprint apparatus 101. If the height distribution (shape) of the substrate 1 is allowable, imprint processing for a plurality of shot regions of the substrate 1 can be executed. The substrate 1 loaded onto the substrate holder 11 may be a substrate including an underlying layer, may be a substrate (for example, a bare silicon wafer) including no underlying layer, or may be a super-flatness wafer. Alternatively, the substrate 1 loaded onto the substrate holder 11 may be a substrate on which the imprint material is arranged or may be a substrate on which the imprint material is not arranged. The substrate 1 loaded onto the substrate holder 11 may be a substrate on which an adhesion layer is not arranged or may be a substrate on which an adhesion layer is arranged, but on which the imprint material is not arranged.

In step S501, the controller 90 controls execution of first measurement of measuring the height of at least one measurement point of the measurement target region of the substrate 1 by the height measurement device 81 and air pressure measurement of measuring the air pressure by the pressure measurement device 80 in synchronism with the first measurement. The first measurement may be performed for a plurality of measurement points of the measurement target region of the substrate 1. As for the number of times of measurement (sampling) at each measurement point, the measurement is preferably performed at least for one period of the variation of the air pressure measured by the pressure measurement device 80.

In step S502, the controller 90 or the calculator 91 calculates or determines the correction coefficient Kw based on the results of the first measurement and the air pressure measurement in step S501. In step S503, the controller 90 controls execution of second measurement of measuring the heights of a plurality of measurement points of the measurement target region of the substrate 1 by the height measurement device 81 and air pressure measurement of measuring the air pressure by the pressure measurement device 80 in synchronism with the second measurement. In step S504, the controller 90 or the calculator 91 corrects the result of the second measurement by the height measurement device 81 based on the correction coefficient Kw calculated or determined in step S502, thereby obtaining shape information representing the shape of the measurement target region of the substrate 1. In other words, in step S504, the controller 90 or the calculator 91 corrects the result of the second measurement by the height measurement device 81 based on the result of the first measurement by the height measurement device 81 and the result of the air pressure measurement by the pressure measurement device 80. Accordingly, the controller 90 or the calculator 91 obtains shape information representing the shape of the measurement target region of the substrate 1.

In step S505, the controller 90 can determine whether the shape information (height distribution) obtained in step S504 is allowable. This determination can be done by, for example, judging whether an index (for example, the maximum height difference of the measurement target region of the substrate 1) obtained from the shape information obtained in step S504 falls within a preset allowable range. If the shape information (height distribution) obtained in step S504 is allowable, the controller 90 can end the measurement processing shown in FIG. 5 and advance to imprint processing. On the other hand, if the shape information (height distribution) obtained in step S504 is not allowable, the controller 90 can make a notification via an interface (not shown) or the like. Steps S501 and S502 may be executed at the time of installation of the imprint apparatus 101 or in a periodical QC step.

Step S501 is an example of the first step of performing first measurement of measuring the height of at least one measurement point of the measurement target region by the height measurement device 81 and air pressure measurement of measuring, by the pressure measurement device 80, the air pressure that influences the result of the first measurement. In the first step, the air pressure measurement can be performed in synchronism with the first measurement. Step S503 is an example of the second step of performing second measurement of measuring the heights of a plurality of measurement points of the measurement target region by the height measurement device 81. Steps S502 and S504 are an example of the third step of obtaining shape information representing the shape of the measurement target region by correcting the result obtained in the second step based on the result obtained in the first step. In the third step, the shape information can be obtained by correcting the result of the second measurement based on the correction coefficient determined in step S502 based on the result of the first step and the result of the air pressure measurement performed in synchronism with the second measurement.

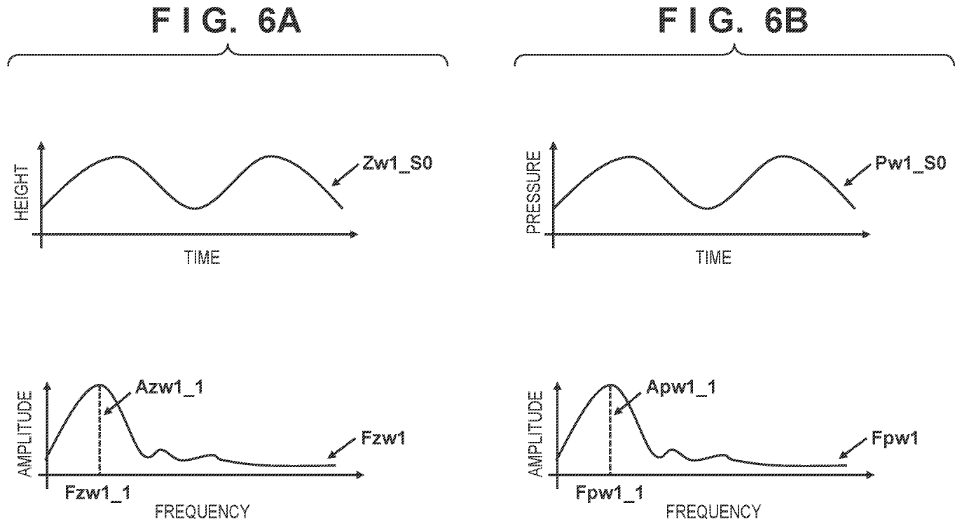

The second embodiment will be described below with reference to FIGS. 6A, 6B, 7A, 7B, and 8. Matters that are not mentioned in the second embodiment can comply with the first embodiment. A measurement method according to the second embodiment can include the first step, the second step, and the third step. In the first step, first measurement of measuring the height of at least one measurement point of a measurement target region and air pressure measurement of measuring the air pressure that influences the result of the first measurement are performed. In the second step, second measurement of measuring the heights of a plurality of measurement points of the measurement target region is performed. In the third step, shape information representing the shape of the measurement target region is obtained by correcting the result obtained in the second step based on the result obtained in the first step. In the first step, the air pressure measurement is performed in synchronism with the first measurement. In the third step, the shape information can be obtained by correcting the result of the second measurement based on a frequency component derived from a variation of the air pressure included in the result of the first measurement.

FIG. 6A shows the result of the first measurement. Zw1 S0 represents a result of measuring the height of an arbitrary measurement point (here, an origin S0) by a height measurement device 81 for a predetermined period in the first measurement. Fzw1 represents a result of performing frequency analysis of Zw1 S0 by a calculator 91 (a result obtained by converting Zw1 S0 into a frequency domain). Fzx1 has an amplitude peak Azw1_1 at a frequency Fzw1_1. FIG. 6B shows the result of air pressure measurement performed in synchronism with the first measurement in the first step. Pw1_S0 represents a result of measurement by a pressure measurement device 80 in the air pressure measurement of the first step. Fpw1 represents a result of performing frequency analysis of Pw1_S0 by the calculator 91. Fpw1 has an amplitude peak Apw1_1 at a frequency Fpw1_1.

The frequency Fpw1_1 can be regarded as the main frequency of the variation of the air pressure. The frequency Fzw1 can have various peaks depending on the arrangement of an imprint apparatus 101 in addition to the influence of the variation of the air pressure in the plant facility. For this reason, even if the frequency representing the peak is obtained by frequency analysis of the result of the first measurement by the height measurement device 81, it is impossible to discriminate whether the frequency is the frequency of the variation of the height caused by the variation of the air pressure. On the other hand, even if the frequency representing the peak is obtained by frequency analysis of the result of the air pressure measurement by the pressure measurement device 80, it is also impossible to discriminate whether the pressure variation at the frequency has an influence on the measurement result of the height of the measurement point of a substrate 1.

Hence, the calculator 91 can compare the main frequency Fpw1_1 of the variation of the air pressure measured by the pressure measurement device 80 with the frequencies of the plurality of peaks in the variation of the height measured by the height measurement device 81. As the result of the comparison, if one of the frequencies of the plurality of peaks in the variation of the height matches the main frequency Fpw1_1 of the variation of the air pressure, the frequency that matches the main frequency Fpw1_1 can be regarded as the frequency of the variation of the measurement result of the height caused by the variation of the air pressure.

Here, let Fw be the frequency that matches the main frequency Fpw1_1 of the variation of the air pressure in the frequencies Fzw1_1 of the plurality of peaks in the variation of the height measured by the height measurement device 81. Fw is given by

Fw=Fpw1_1 (9)

If none of the frequencies Fzw1_1 of the plurality of peaks in the variation of the height measured by the height measurement device 81 matches the main frequency Fpw1_1, it can be considered that the influence of the variation of the air pressure does not exist in the height measurement of the substrate 1. An example in which the origin S0 on the substrate 1 is set to the measurement point in the first measurement has been described here. However, the measurement point in the first measurement can arbitrarily be determined. In the second embodiment as well, the first measurement by the height measurement device 81 and the measurement of the air pressure by the pressure measurement device 80 are preferably performed at least for one period of the variation of the air pressure. If the period is shorter than one period, a high frequency component that cannot exist originally is added as the measurement result, and therefore, there may be a possibility that a desired result cannot be obtained.

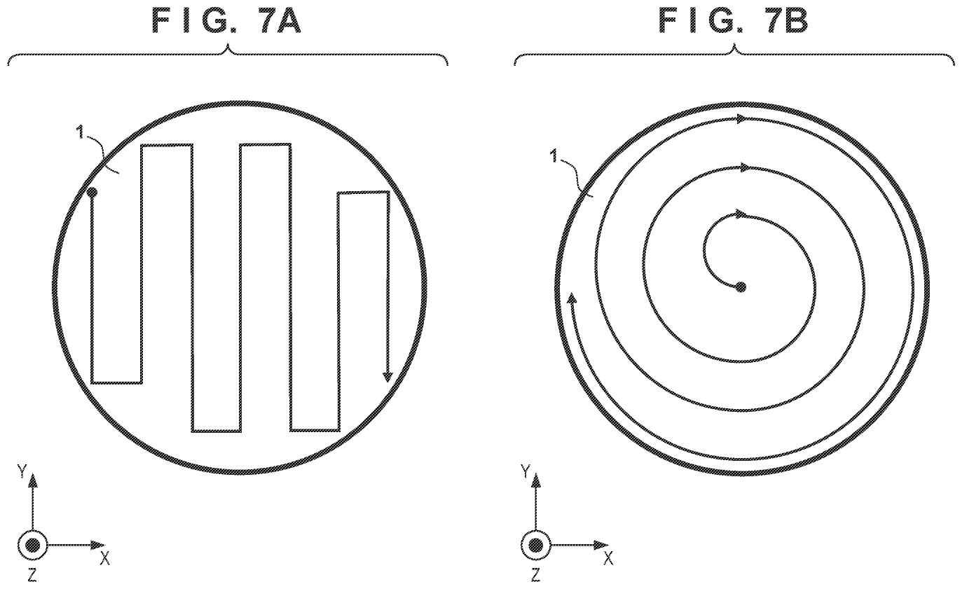

FIGS. 7A and 7B schematically show two examples of second measurement of measuring the heights of a plurality of measurement points of the measurement target region of the substrate 1 by the height measurement device 81. The second measurement is preferably executed such that the measurement time intervals become constant for all measurement points in the measurement target region of the substrate 1. This is because a desired calculation result cannot be obtained if the measurement time intervals are not constant when frequency-analyzing the result of the second measurement by the calculator 91. FIG. 7A shows an example in which a movable body 21 is moved in a rectangular wave shape when the height measurement device 81 measures heights at a plurality of measurement points of the substrate 1. FIG. 7B shows an example in which the movable body 21 is moved spirally when the height measurement device 81 measures heights at a plurality of measurement points of the substrate 1. The arrangement of the plurality of measurement points of the substrate 1 in the second measurement is not limited to the examples shown in FIGS. 7A and 7B, and another arrangement may be employed.

The calculator 91 can perform frequency analysis of the measurement result of the height obtained by the second measurement by the height measurement device 81 and determine whether the component of the frequency Fw is included. If the component of the frequency Fw is included in the measurement result of the height obtained by the second measurement by the height measurement device 81, the calculator 91 can remove the component of the frequency Fw from a result Zw2(x, y) of the measurement in the second measurement by the height measurement device 81. This makes it possible to obtain a height distribution Zwt1(x, y) in the measurement target region of the substrate 1, from which the variation of the air pressure is removed.

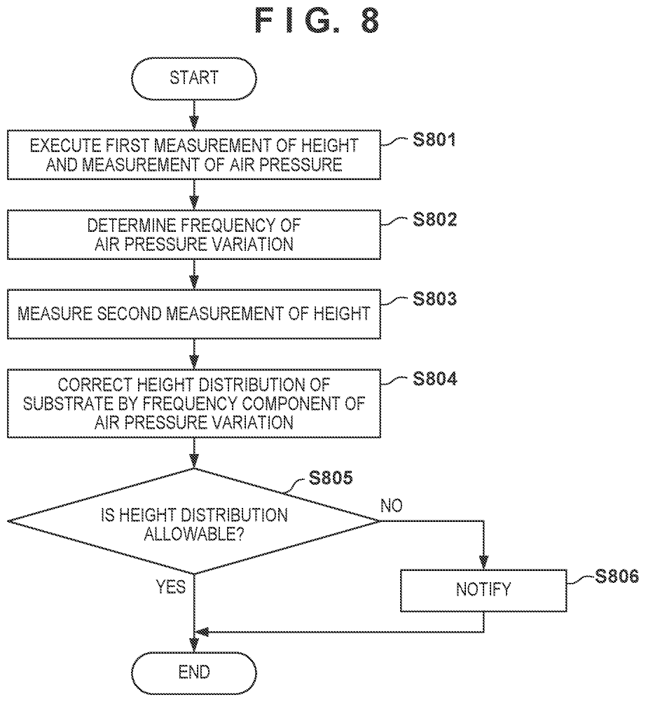

FIG. 8 shows a measurement method according to the second embodiment. The measurement method shown in FIG. 8 can be controlled by a controller 90. The measurement method shown in FIG. 8 can be incorporated in a procedure of controlling imprint processing. For example, the measurement method shown in FIG. 8 is executed when the substrate 1 is loaded onto a substrate holder 11 of the imprint apparatus 101. If the height distribution (shape) of the substrate 1 is allowable, imprint processing for a plurality of shot regions of the substrate 1 can be executed.

In step S801, the controller 90 controls execution of first measurement of measuring the height of at least one measurement point of the measurement target region of the substrate 1 by the height measurement device 81 and air pressure measurement of measuring the air pressure by the pressure measurement device 80 in synchronism with the first measurement. The first measurement may be performed for a plurality of measurement points of the measurement target region of the substrate 1. As for the number of times of measurement (sampling) at each measurement point, the measurement is preferably performed at least for one period of the variation of the air pressure measured by the pressure measurement device 80.

In step S802, the controller 90 or the calculator 91 calculates or determines the frequency Fw of the variation of the air pressure by frequency analysis based on the results of the first measurement and the air pressure measurement in step S801. In step S803, the controller 90 controls execution of second measurement of measuring the heights of a plurality of measurement points of the measurement target region of the substrate 1 by the height measurement device 81. In step S804, the controller 90 or the calculator 91 corrects the result of the second measurement by the height measurement device 81 based on the component of the frequency Fw calculated or determined in step S802, thereby obtaining shape information representing the shape of the measurement target region of the substrate 1. In other words, in step S804, the controller 90 or the calculator 91 corrects the result of the second measurement by the height measurement device 81 based on the result of the first measurement by the height measurement device 81 and the result of the air pressure measurement by the pressure measurement device 80. Accordingly, the controller 90 or the calculator 91 obtains shape information representing the shape of the measurement target region of the substrate 1.

In step S805, the controller 90 can determine whether the shape information (height distribution) obtained in step S804 is allowable. This determination can be done by, for example, judging whether an index (for example, the maximum height difference of the measurement target region of the substrate 1) obtained from the shape information obtained in step S804 falls within a preset allowable range. If the shape information (height distribution) obtained in step S804 is allowable, the controller 90 can end the measurement processing shown in FIG. 8 and advance to imprint processing. On the other hand, if the shape information (height distribution) obtained in step S804 is not allowable, the controller 90 can make a notification via an interface (not shown) or the like. Steps S801 and S802 may be executed at the time of installation of the imprint apparatus 101 or in a periodical QC step.

Step S801 is an example of the first step of performing first measurement of measuring the height of at least one measurement point of the measurement target region by the height measurement device 81 and air pressure measurement of measuring, by the pressure measurement device 80, the air pressure that influences the result of the first measurement. In the first step, the air pressure measurement can be performed in synchronism with the first measurement. Step S803 is an example of the second step of performing second measurement of measuring the heights of a plurality of measurement points of the measurement target region by the height measurement device 81. Steps S802 and S804 are an example of the third step of obtaining shape information representing the shape of the measurement target region by correcting the result obtained in the second step based on the result obtained in the first step. In the third step, the shape information can be obtained by correcting the result of the second measurement based on the frequency component derived from the variation of the air pressure included in the result of the first measurement.

In the first and second embodiments, the height distribution (shape) of the measurement target region or the surface of the substrate 1 is measured. Instead, the height distribution (shape) of the substrate holding surface of the substrate holder 11 may be measured. In this case, the measurement target region can include at least a part of the substrate holding surface of the substrate holder 11.

In the first and second embodiments, the height of the movable body 21 varies due to the variation of the air pressure, and this influences the results of the first measurement and the second measurement by the height measurement device 81. In the third and fourth embodiments to be described below, the height distribution (shape) of the measurement target region of the mold 41 is measured by a height measurement device 82 supported by the movable body 21. The height of the movable body 21 varies due to the variation of the air pressure, and this influences the results of first measurement and second measurement by a height measurement device 82.

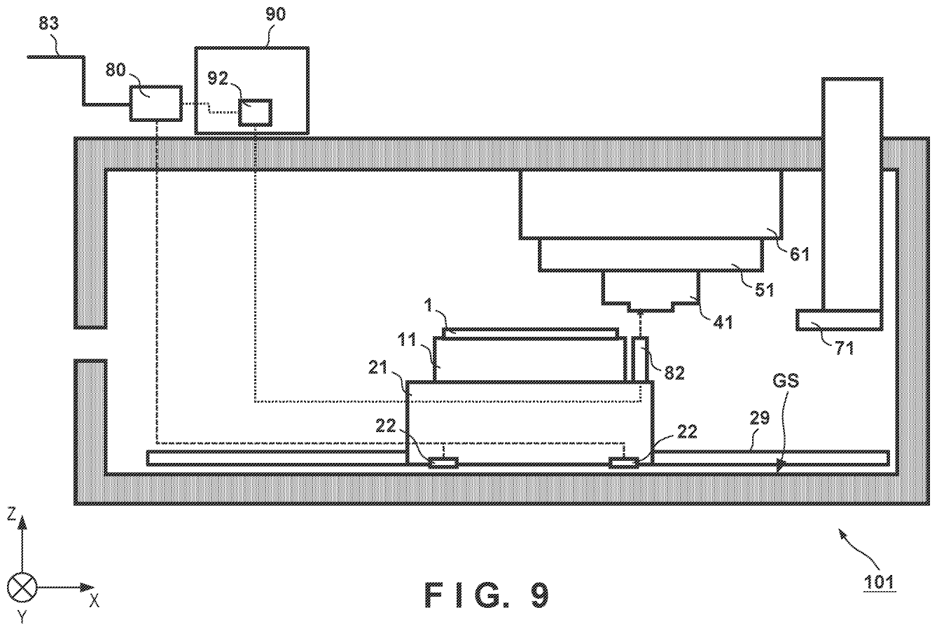

The third embodiment will be described below with reference to FIGS. 9, 10A, 10B, 11, and 12. Matters that are not mentioned in the third embodiment can comply with the first embodiment. FIG. 9 shows the arrangement of an imprint apparatus 101 according to the third embodiment. The imprint apparatus 101 brings an imprint material on a shot region of a substrate 1 into contact with the pattern surface of a mold 41, and cures the imprint material, thereby forming a pattern of the imprint material on the shot region. Points different from the imprint apparatus 101 according to the first embodiment will be described here. The imprint apparatus 101 includes a height measurement device 82 supported by a movable body 21, and the height measurement device 82 is configured to, for example, measure the height of the measurement target region of the mold 41. The measurement target region of the mold 41 can, for example, include at least a part of the pattern surface of the mold 41. The imprint apparatus 101 can include a mold conveying mechanism 71 that loads the mold 41 onto a mold holder 51 or unloads the mold 41 from the mold holder 51 to the outside of the imprint apparatus 101. A measurement method according to the third embodiment can include the first step, the second step, and the third step. In the first step, first measurement of measuring the height of at least one measurement point of the measurement target region of the mold 41 and air pressure measurement of measuring the air pressure that influences the result of the first measurement are performed. In the first step, the air pressure measurement can be performed in synchronism with the first measurement. In the second step, second measurement of measuring the heights of a plurality of measurement points of the measurement target region of the mold 41 is performed. In the second step, the air pressure measurement can be performed in synchronism with the second measurement. In the third step, shape information representing the shape of the measurement target region of the mold 41 is obtained by correcting the result obtained in the second step based on the result obtained in the first step. In the third step, the shape information representing the shape of the measurement target region of the mold 41 can be obtained by correcting the result of the second measurement based on a correction coefficient determined based on the result of the first step and the result of the air pressure measurement performed in synchronism with the second measurement.

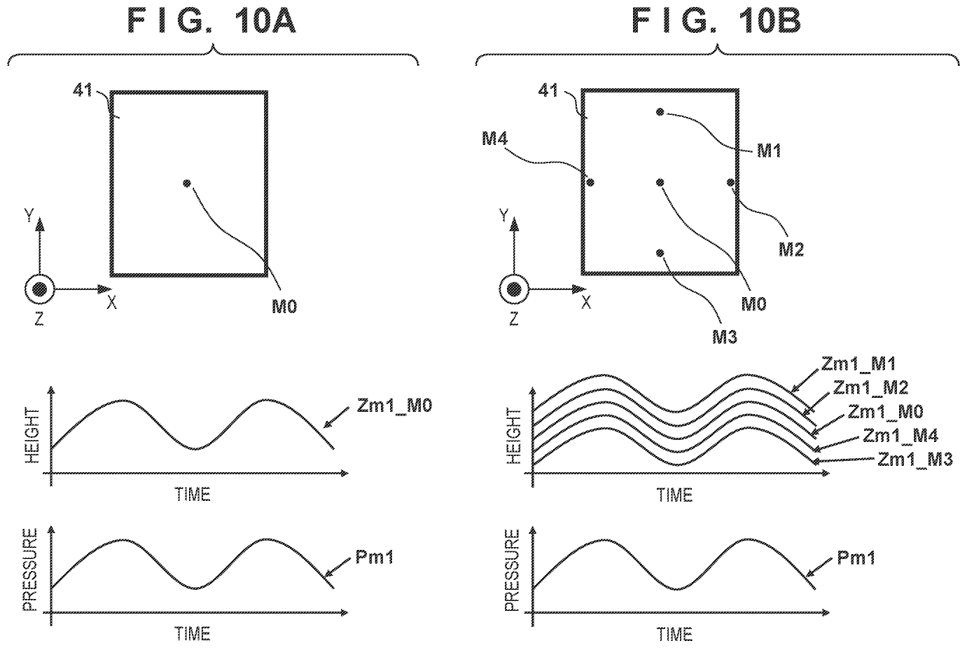

FIGS. 10A and 10B schematically show first measurement of measuring the height of at least one measurement point of the measurement target region of the mold 41 by the height measurement device 82. Here, a result of measuring the height (the position in the Z direction) of a measurement point in the measurement target region of the mold 41 by the height measurement device 82 is indicated by a symbol including Zm1, and the pressure of air measured by a pressure measurement device 80 in synchronism with the height measurement device 82 is indicated by Pm1. A suffix added to Zm1 represents the position of the measurement target point in the horizontal direction (X and Y directions).

FIG. 10A shows the result of measuring a variation of the height at the measurement point using, as the measurement point, one measurement point (here, an origin M0) on an XY coordinate system with the origin at the center of the mold 41. It can be considered that a proportional relationship holds in a very small region (for example, a submicron order) between a variation width ΔZm1 of the height measurement result by the height measurement device 82 and a variation width ΔPm1 of the pressure measurement result by the pressure measurement device 80 at the origin M0. Hence, letting Km0 be the correction coefficient at the origin M0,

ΔZm1_M0=Km0×ΔPm1_M0 (10)

holds.

The height of the movable body 21 that almost maintains the horizontal posture varies in accordance with equation (10). Hence, letting Km be the correction coefficient used to correct the height measured by the height measurement device 82, the correction coefficient Km used when the height is measured only at the origin M0 can be given by

Km=Km0 (11)

FIG. 10B shows the result of measuring a variation of the height at each of the measurement points using, as the measurement points, the origin M0 on the XY coordinate system with the origin at the center of the mold 41, points M2 and M4 on the X-axis, and points M1 and M3 on the Y axis. As in the above-described case, it can be considered that a proportional relationship holds in a very small region between the variation width ΔZm1 of the height measurement result by the height measurement device 82 and the variation width ΔPm1 of the pressure measurement result by the pressure measurement device 80 at each measurement point. Hence, letting KM1, KM2, KM3, and KM4 be the coefficients, equations (12), (13), (14), and (15) are obtained. A suffix represents a measurement point.

ΔZm1_M1=Km1×ΔPm1_M1 (12)

ΔZm1_M2=Km2×ΔPm1_M2 (13)

ΔZm1_M3=Km3×ΔPm1_M3 (14)

ΔZm1_M4=Km4×ΔPm1_M4 (15)

Since the height of the movable body 21 changes following the variation of the air pressure in accordance with equations (10), (12), (13), (14), and (15), the correction coefficient Km used when the heights of the five measurement points M0 to M4 are measured can be given by

Km=(KM4−KM2)÷(KM4_x−KM2_x)×X+(KM3−KM1)÷(KM3_y−KM1_y)×Y+KM0 (16)

where KM2_x and KM4_x represent the x-coordinates of the measurement points M2 and M4, and KM1_y and KM3_y represent the y-coordinates of the measurement points M1 and M3. In addition, X and Y represent an arbitrary point on the mold 41 on the XY coordinate system.

In this example, the measurement points are set to the origin M0, the points M2 and M4 on the X-axis, and the points M1 and M3 on the Y-axis. However, the number and positions of measurement points are not limited to this example, and arbitrary points on the mold 41 can be set to measurement points. In addition, the first measurement by the height measurement device 82 and the air pressure measurement by the pressure measurement device 80 are preferably performed at least for one period of the variation of the air pressure.

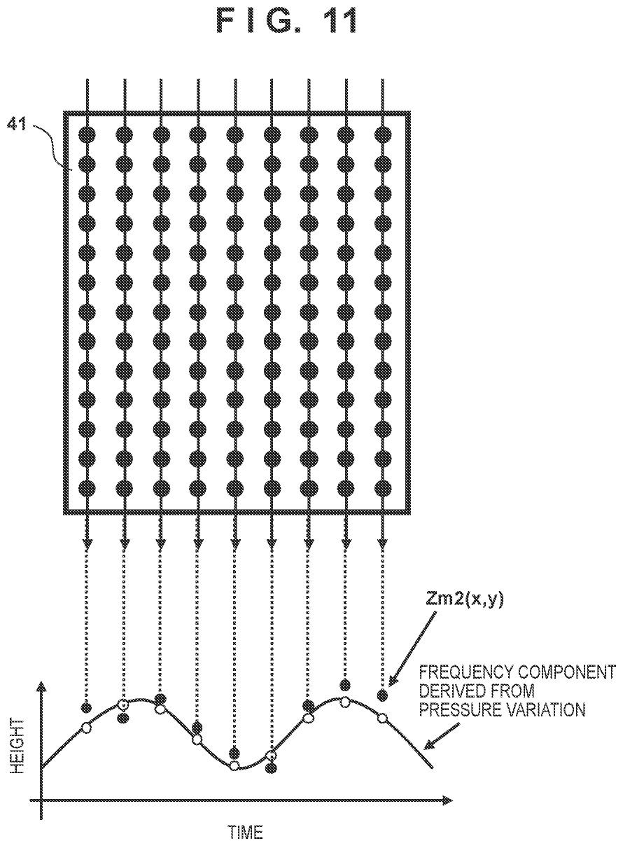

FIG. 11 schematically shows second measurement of measuring the heights of a plurality of measurement points of the measurement target region of the mold 41 by the height measurement device 82. The plurality of measurement points of the measurement target region in the second measurement can be determined such that the measurement points are arranged on each of a plurality of lines parallel to the Y direction. Let Zm2(x, y) be the result of measurement in the second measurement by the height measurement device 82, and Pm2(x, y) be the result of measurement by the pressure measurement device 80 in synchronism with the height measurement device 82. Since Zm2(x, y) varies following the variation of the air pressure measured by the pressure measurement device 80, a distribution Zmt1(x, y) of heights in the measurement target region of the mold 41 after the variation of the air pressure is removed is given by

Zmt1(x,y)=Zm2(x,y)−Km×(Pm2(x,y)−Pm2(0,0)) (17)

where Pm2(0, 0) is a pressure measured by the pressure measurement device 80 when measuring the height of the origin (0, 0) of the XY coordinate system on the mold 41. However, an arbitrary point on the mold 41 can be set to the reference point. In addition, the arrangement of the plurality of measurement points in the second measurement by the height measurement device 82 may be determined such that the measurement points are arranged on each of a plurality of lines parallel to the X direction. Alternatively, the arrangement of the plurality of measurement points in the second measurement by the height measurement device 82 may be determined such that the measurement points are arranged on each of a plurality of lines in an oblique direction with respect to the X or Y direction. Alternatively, the arrangement of the plurality of measurement points in the second measurement by the height measurement device 82 may be determined such that the plurality of measurement points are arranged on a spiral line.

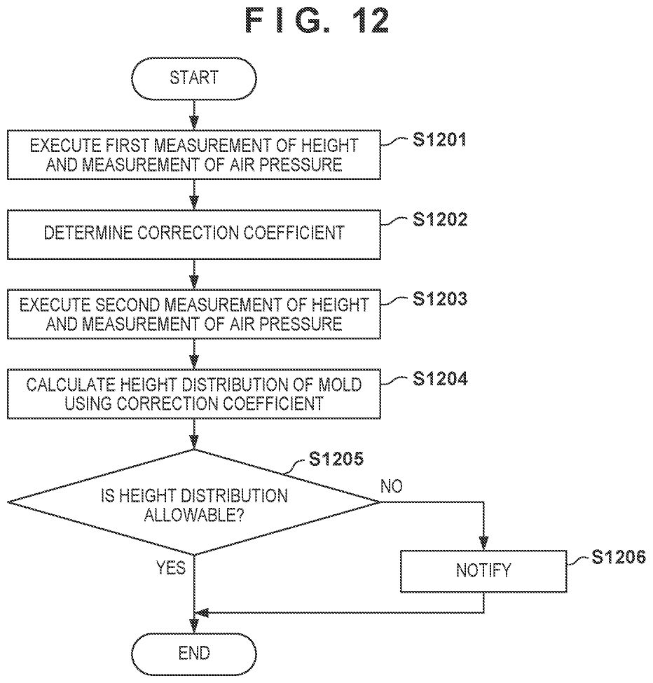

FIG. 12 shows a measurement method according to the third embodiment. The measurement method shown in FIG. 12 can be controlled by the controller 90. The measurement method shown in FIG. 12 can be incorporated in a procedure of controlling imprint processing. For example, the measurement method shown in FIG. 12 is executed when the mold 41 is loaded onto the mold holder 51 of the imprint apparatus 101. If the height distribution (shape) of the mold 41 is allowable, imprint processing for a plurality of shot regions of the substrate 1 can be executed. The mold 41 loaded onto the mold holder 51 may have a concave portion (cavity) on the side of the mold holder 51 or not.

In step S1201, the controller 90 controls execution of first measurement of measuring the height of at least one measurement point of the measurement target region of the mold 41 by the height measurement device 82 and air pressure measurement of measuring the air pressure by the pressure measurement device 80 in synchronism with the first measurement. The first measurement may be performed for a plurality of measurement points of the measurement target region of the mold 41. As for the number of times of measurement (sampling) at each measurement point, the measurement is preferably performed at least for one period of the variation of the air pressure measured by the pressure measurement device 80.

In step S1202, the controller 90 or the calculator 91 calculates or determines the correction coefficient Km based on the results of the first measurement and the air pressure measurement in step S1201. In step S1203, the controller 90 controls execution of second measurement of measuring the heights of a plurality of measurement points of the measurement target region of the mold 41 by the height measurement device 82 and air pressure measurement of measuring the air pressure by the pressure measurement device 80 in synchronism with the second measurement. In step S1204, the controller 90 or the calculator 91 corrects the result of the second measurement by the height measurement device 82 based on the correction coefficient Km calculated or determined in step S1202, thereby obtaining shape information representing the shape of the measurement target region of the mold 41. In other words, in step S1204, the controller 90 or the calculator 91 corrects the result of the second measurement by the height measurement device 82 based on the result of the first measurement by the height measurement device 82 and the result of the air pressure measurement by the pressure measurement device 80. Accordingly, the controller 90 or the calculator 91 obtains shape information representing the shape of the measurement target region of the mold 41.

In step S1205, the controller 90 can determine whether the shape information (height distribution) obtained in step S1204 is allowable. This determination can be done by, for example, judging whether an index (for example, the maximum height difference of the measurement target region of the mold 41) obtained from the shape information obtained in step S1204 falls within a preset allowable range. If the shape information (height distribution) obtained in step S1204 is allowable, the controller 90 can end the measurement processing shown in FIG. 12 and advance to imprint processing. On the other hand, if the shape information (height distribution) obtained in step S1204 is not allowable, the controller 90 can make a notification via an interface (not shown) or the like. Steps S1201 and S1202 may be executed at the time of installation of the imprint apparatus 101 or in a periodical QC step.

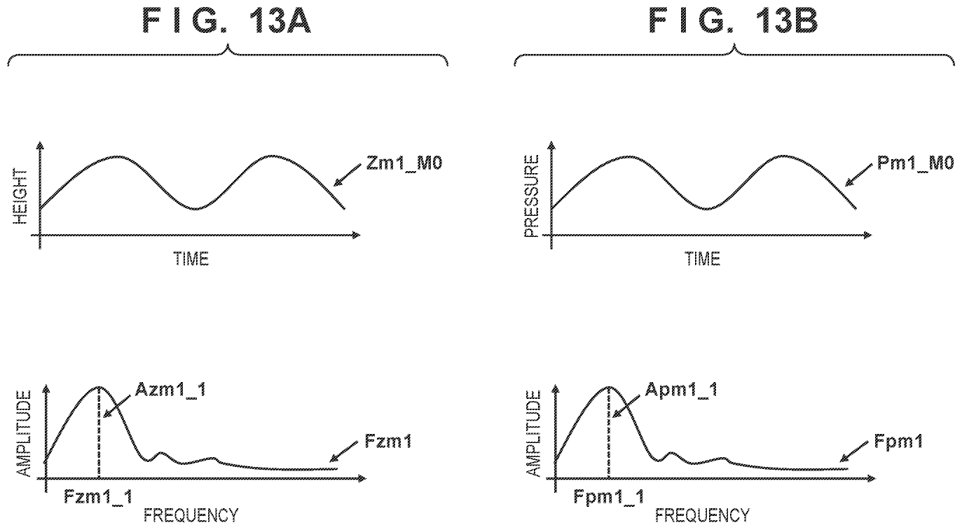

The fourth embodiment will be described below with reference to FIGS. 13A, 13B, 14A, 14B, and 15. Matters that are not mentioned in the fourth embodiment can comply with the second embodiment. A measurement method according to the fourth embodiment can include the first step, the second step, and the third step. In the first step, first measurement of measuring the height of at least one measurement point of the measurement target region of a mold 41 and air pressure measurement of measuring the air pressure that influences the result of the first measurement are performed. In the second step, second measurement of measuring the heights of a plurality of measurement points of the measurement target region of the mold 41 is performed. In the third step, shape information representing the shape of the measurement target region of the mold 41 is obtained by correcting the result obtained in the second step based on the result obtained in the first step. In the first step, the air pressure measurement is performed in synchronism with the first measurement. In the third step, the shape information representing the shape of the measurement target region of the mold 41 can be obtained by correcting the result of the second measurement based on a frequency component derived from a variation of the air pressure included in the result of the first measurement.

FIG. 13A shows the result of the first measurement. Zm1_M0 represents a result of measuring the height of an arbitrary measurement point (here, an origin M0) by a height measurement device 82 for a predetermined period in the first measurement. Fzm1 represents a result of performing frequency analysis of Zm1_M0 by a calculator 91. Fzm1 has an amplitude peak Azm1_1 at a frequency Fzm1_1. FIG. 13B shows the result of air pressure measurement performed in synchronism with the first measurement in the first step. Pm1_M0 represents a result of measurement by a pressure measurement device 80 in the air pressure measurement of the first step. Fpm1 represents a result of performing frequency analysis of Pm1_M0 by the calculator 91. Fpm1 has an amplitude peak Apm1_1 at a frequency Fpm1_1.

The frequency Fpm1_1 can be regarded as the main frequency of the variation of the air pressure. The frequency Fzm1 can have various peaks depending on the arrangement of an imprint apparatus 101 in addition to the influence of the variation of the air pressure in the plant facility. For this reason, even if the frequency representing the peak is obtained by frequency analysis of the result of the first measurement by the height measurement device 82, it is impossible to discriminate whether the frequency is the frequency of the variation of the height caused by the variation of the air pressure. On the other hand, even if the frequency representing the peak is obtained by frequency analysis of the result of the air pressure measurement by the pressure measurement device 80, it is also impossible to discriminate whether the pressure variation at the frequency has an influence on the measurement result of the height of the measurement point of the mold 41.

Hence, the calculator 91 can compare the main frequency Fpm1_1 of the variation of the air pressure measured by the pressure measurement device 80 with the frequencies of the plurality of peaks in the variation of the height measured by the height measurement device 82. As the result of the comparison, if one of the frequencies of the plurality of peaks in the variation of the height matches the main frequency Fpm1_1 of the variation of the air pressure, the frequency that matches the main frequency Fpm1_1 can be regarded as the frequency of the variation of the measurement result of the height caused by the variation of the air pressure.

Here, let Fm be the frequency that matches the main frequency Fpm1_1 of the variation of the air pressure in the frequencies Fzm1_1 of the plurality of peaks in the variation of the height measured by the height measurement device 82. Fm is given by

Fm=Fpm1_1 (18)

If none of the frequencies Fzm1_1 of the plurality of peaks in the variation of the height measured by the height measurement device 82 matches the main frequency Fpm1_1, it can be considered that the influence of the variation of the air pressure does not exist in the height measurement of the mold 41. An example in which the origin M0 on the mold 41 is set to the measurement point in the first measurement has been described here. However, the measurement point in the first measurement can arbitrarily be determined. In the fourth embodiment as well, the first measurement by the height measurement device 82 and the measurement of the air pressure by the pressure measurement device 80 are preferably performed at least for one period of the variation of the air pressure. If the period is shorter than one period, a high frequency component that cannot exist originally is added as the measurement result, and therefore, there may be a possibility that a desired result cannot be obtained.

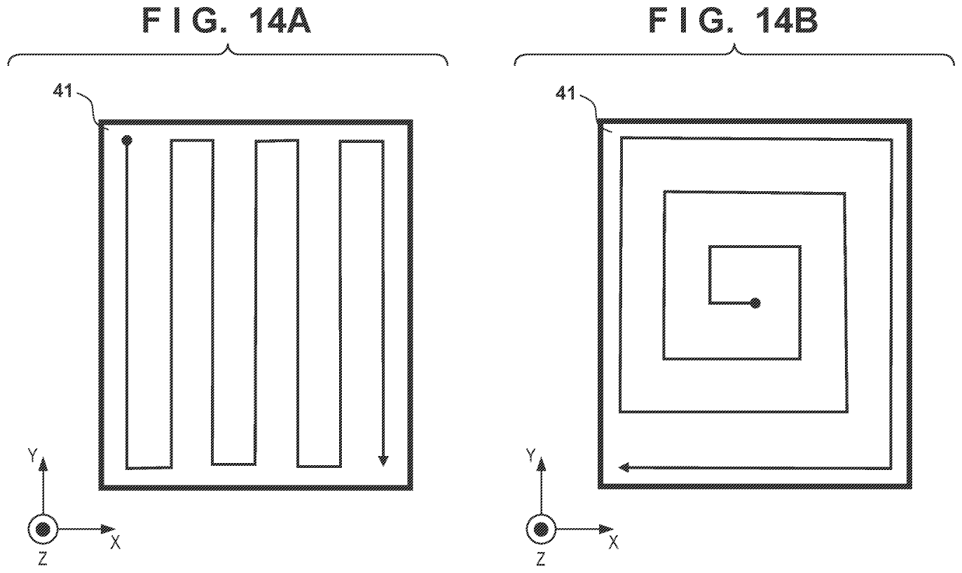

FIGS. 14A and 14B schematically show two examples of second measurement of measuring the heights of a plurality of measurement points of the measurement target region of the mold 41 by the height measurement device 82. The second measurement is preferably executed such that the measurement time intervals become constant for all measurement points in the measurement target region of the mold 41. This is because a desired calculation result cannot be obtained if the measurement time intervals are not constant when frequency-analyzing the result of the second measurement by the calculator 91. FIG. 14A shows an example in which a movable body 21 is moved in a rectangular wave shape when the height measurement device 82 measures heights at a plurality of measurement points of the mold 41. FIG. 14B shows an example in which the movable body 21 is moved spirally when the height measurement device 82 measures heights at a plurality of measurement points of the mold 41. The arrangement of the plurality of measurement points of the mold 41 in the second measurement is not limited to the examples shown in FIGS. 14A and 14B, and another arrangement may be employed. The measurement target region of the mold 41 may be limited to only the pattern surface of the mold 41.

The calculator 91 can perform frequency analysis of the measurement result of the height obtained by the second measurement by the height measurement device 82 and determine whether the component of the frequency Fm is included. If the component of the frequency Fm is included in the measurement result of the height obtained by the second measurement by the height measurement device 82, the calculator 91 can remove the component of the frequency Fm from a result Zm2(x, y) of the measurement in the second measurement by the height measurement device 82. This makes it possible to obtain a height distribution Zmt1 (x, y) in the measurement target region of the mold 41, from which the variation of the air pressure is removed.

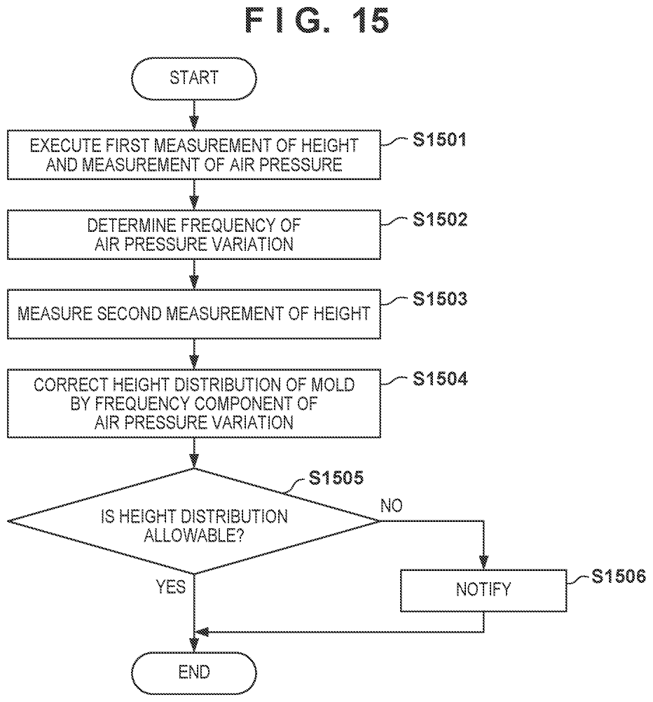

FIG. 15 shows a measurement method according to the fourth embodiment. The measurement method shown in FIG. 15 can be controlled by a controller 90. The measurement method shown in FIG. 15 can be incorporated in a procedure of controlling imprint processing. For example, the measurement method shown in FIG. 15 is executed when the mold 41 is loaded onto a mold holder 51 of the imprint apparatus 101. If the height distribution (shape) of the mold 41 is allowable, imprint processing for a plurality of shot regions of a substrate 1 can be executed.

In step S1501, the controller 90 controls execution of first measurement of measuring the height of at least one measurement point of the measurement target region of the mold 41 by the height measurement device 82 and air pressure measurement of measuring the air pressure by the pressure measurement device 80 in synchronism with the first measurement. The first measurement may be performed for a plurality of measurement points of the measurement target region of the mold 41. As for the number of times of measurement (sampling) at each measurement point, the measurement is preferably performed at least for one period of the variation of the air pressure measured by the pressure measurement device 80.

In step S1502, the controller 90 or the calculator 91 calculates or determines the frequency Fm of the variation of the air pressure by frequency analysis based on the results of the first measurement and the air pressure measurement in step S1501. In step S1503, the controller 90 controls execution of second measurement of measuring the heights of a plurality of measurement points of the measurement target region of the mold 41 by the height measurement device 82. In step S1504, the controller 90 or the calculator 91 corrects the result of the second measurement by the height measurement device 82 based on the component of the frequency Fm calculated or determined in step S1502, thereby obtaining shape information representing the shape of the measurement target region of the mold 41. In other words, in step S1504, the controller 90 or the calculator 91 corrects the result of the second measurement by the height measurement device 82 based on the result of the first measurement by the height measurement device 82 and the result of the air pressure measurement by the pressure measurement device 80. Accordingly, the controller 90 or the calculator 91 obtains shape information representing the shape of the measurement target region of the mold 41.

In step S1505, the controller 90 can determine whether the shape information (height distribution) obtained in step S1504 is allowable. This determination can be done by, for example, judging whether an index (for example, the maximum height difference of the measurement target region of the mold 41) obtained from the shape information obtained in step S1504 falls within a preset allowable range. If the shape information (height distribution) obtained in step S1504 is allowable, the controller 90 can end the measurement processing shown in FIG. 15 and advance to imprint processing. On the other hand, if the shape information (height distribution) obtained in step S1504 is not allowable, the controller 90 can make a notification via an interface (not shown) or the like. Steps S1501 and S1502 may be executed at the time of installation of the imprint apparatus 101 or in a periodical QC step.

Step S1501 is an example of the first step of performing first measurement of measuring the height of at least one measurement point of the measurement target region by the height measurement device 82 and air pressure measurement of measuring, by the pressure measurement device 80, the air pressure that influences the result of the first measurement. In the first step, the air pressure measurement can be performed in synchronism with the first measurement. Step S1503 is an example of the second step of performing second measurement of measuring the heights of a plurality of measurement points of the measurement target region by the height measurement device 82. Steps S1502 and S1504 are an example of the third step of obtaining shape information representing the shape of the measurement target region by correcting the result obtained in the second step based on the result obtained in the first step. In the third step, the shape information can be obtained by correcting the result of the second measurement based on the frequency component derived from the variation of the air pressure included in the result of the first measurement.

In the third and fourth embodiments, the height distribution (shape) of the measurement target region or the surface of the mold 41 is measured. Instead, the height distribution (shape) of the mold holding surface of the mold holder 51 may be measured. In this case, the measurement target region can include at least a part of the mold holding surface of the mold holder 51.

An article manufacturing method according to an embodiment will be described below. An article manufacturing method of manufacturing a device (for example, a semiconductor integrated circuit element or a liquid crystal display element) as an article includes a forming step of forming a pattern on a substrate (a wafer, a glass plate, or a film-shaped substrate) using the above-described imprint apparatus. The manufacturing method can also include a processing step of processing (for example, etching) the substrate with the pattern being formed. Note that when manufacturing another article such as a pattered medium (recording medium) or an optical element, the manufacturing method can include another process of processing the substrate with the pattern being formed in place of etching. The article manufacturing method according to this embodiment is superior to a conventional method in at least one of the quality, productivity, and production cost of the article.

### OTHER EMBODIMENTS

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2020-089073, filed May 21, 2020, which is hereby incorporated by reference herein in its entirety.

What is claimed is:

1. A processing apparatus comprising:
a height measurement device configured to perform first measurement of measuring a height of at least one measurement point of a measurement target region and second measurement of measuring heights of a plurality of measurement points of the measurement target region;
a pressure measurement device configured to measure an air pressure that influences results of the first measurement and the second measurement by the height measurement device; and
a calculator configured to obtain shape information representing a shape of the measurement target region by correcting the result of the second measurement by the height measurement device based on the result of the first measurement by the height measurement device and a result of measurement of the air pressure by the pressure measurement device.

2. The apparatus according to claim 1, wherein
the pressure measurement device performs the measurement of the air pressure in synchronism with the first measurement and performs the measurement of the air pressure in synchronism with the second measurement, and
the calculator determines a correction coefficient based on the result of the first measurement and the result of the measurement of the air pressure performed in synchronism with the first measurement, and obtains the shape information by correcting the result of the second measurement based on the correction coefficient and the result of the measurement of the air pressure performed in synchronism with the second measurement.

3. The apparatus according to claim 2, wherein the first measurement by the height measurement device and the measurement of the air pressure by the pressure measurement device are performed at least for one period of a variation of the air pressure.

4. The apparatus according to claim 1, wherein
the pressure measurement device performs the measurement of the air pressure in synchronism with the first measurement, and
the calculator obtains the shape information by correcting the result of the second measurement based on a frequency component derived from a variation of the air pressure included in the result of the first measurement.

5. The apparatus according to claim 4, wherein in a case where a frequency representing a peak in a result of frequency analysis of the result of the first measurement and a frequency representing a peak in a result of frequency analysis of the result of the second measurement match, the calculator obtains the shape information by correcting the result of the second measurement based on the frequency representing the peak.

6. The apparatus according to claim 1, wherein processing of bringing a mold into contact with an imprint material on a substrate and curing the imprint material is performed.

7. The apparatus according to claim 6, wherein
the measurement target region includes at least a part of a surface of the substrate, and
the substrate is held by a substrate holder mounted on a movable body floated by the air pressure above a guide surface.

8. The apparatus according to claim 6, wherein the measurement target region includes at least a part of a substrate holding surface of a substrate holder provided on a movable body floated by the air pressure above a guide surface and configured to hold the substrate.

9. The apparatus according to claim 6, wherein
the measurement target region includes at least a part of a surface of the mold, and
the measurement device is supported by a movable body floated by the air pressure above a guide surface.

10. A measurement method comprising:
performing first measurement of measuring a height of at least one measurement point of a measurement target region and air pressure measurement of measuring an air pressure that influences a result of the first measurement;
performing second measurement of measuring heights of a plurality of measurement points of the measurement target region; and
obtaining shape information representing a shape of the measurement target region by correcting a result obtained in the performing the second measurement based on a result obtained in the performing the first measurement.

11. The method according to claim 10, wherein
in the performing the first measurement, the air pressure measurement is performed in synchronism with the first measurement,
in the performing the second measurement, the air pressure measurement is performed in synchronism with the second measurement; and
in the obtaining the shape information, the shape information is obtained by correcting a correction coefficient determined based on the result in the performing the first measurement and the result of the air pressure measurement performed in synchronism with the second measurement.

12. The method according to claim 11, wherein the performing the first measurement is performed at least for one period of a variation of the air pressure.

13. The method according to claim 10, wherein
in the performing the first measurement, the air pressure measurement is performed in synchronism with the first measurement, and
in the obtaining the shape information, the shape information is obtained by correcting the result of the second measurement based on a frequency component derived from a variation of the air pressure included in the result of the first measurement.

14. The method according to claim 13, wherein in the obtaining the shape information, in a case where a frequency representing a peak in a result of frequency analysis of the result of the first measurement and a frequency representing a peak in a result of frequency analysis of the result of the second measurement match, the shape information is obtained by correcting the result of the second measurement based on the frequency representing the peak.

15. The method according to claim 10, wherein
the performing the first measurement, the performing the second measurement, and the obtaining the shape information are executed in an imprint apparatus for performing processing of bringing a mold into contact with an imprint material on a substrate and curing the imprint material,
the measurement target region includes at least a part of a surface of the substrate, and
the substrate is held by a substrate holder mounted on a movable body floated by the air pressure above a guide surface.

16. The method according to claim 10, wherein
the performing the first measurement, the performing the second measurement, and the obtaining the shape information are executed in an imprint apparatus for performing processing of bringing a mold into contact with an imprint material on a substrate and curing the imprint material,
the measurement target region includes at least a part of a substrate holding surface of a substrate holder provided on a movable body floated by the air pressure above a guide surface and configured to hold the substrate.

17. The method according to claim 10, wherein
the performing the first measurement, the performing the second measurement, and the obtaining the shape information are executed in an imprint apparatus for performing processing of bringing a mold into contact with an imprint material on a substrate and curing the imprint material,
the measurement target region includes at least a part of a surface of the mold, and
in the performing the first measurement and the performing the second measurement, a measurement device configured to measure a height of the measurement target region is supported by a movable body floated by the air pressure above a guide surface.

18. An article manufacturing method comprising:
forming a pattern on a substrate using a processing apparatus of claim 6; and
processing the substrate with the pattern being formed in the forming,
wherein an article is manufactured from the substrate that has undergone the processing.
